(19) United States
(12) Patent Application Publication
(10) Pub. No.: US 2022/0059374 A1
(43) Pub. Date: Feb. 24, 2022

(54) MOUNTING AND FASTENING OF INDIVIDUAL ELEMENTS ON A SUBSTRATE WEB

(71) Applicant: GIESECKE+DEVRIENT CURRENCY TECHNOLOGY GMBH, Munchen (DE)

(72) Inventors: Mario KELLER, Seebruck (DE); Maik Rudolf Johann SCHERER, Grainau (DE); Michael RAHM, Bad Tolz (DE)

(21) Appl. No.: 17/299,067

(22) PCT Filed: Dec. 3, 2019
(86) PCT No.: PCT/EP2019/025426

§ 371 Date: Jun. 2, 2021

(30) Foreign Application Priority Data
Dec. 3, 2018 (DE) 10 2018 009 475.9

(51) Int. Cl. H01L 21/67; H01L 23/00; G06K 19/07

(52) U.S. Cl. CPC H01L 21/67132; H01L 21/67144; B42D 25/29; G06K 19/07; H01L 2224/95101; H01L 24/95

(57) ABSTRACT

The invention relates to a method and a device for mounting and fastening individual elements at predetermined positions on a surface of a moving substrate web. According to the invention, the device has a rotary cylinder or a circulating belt, wherein the rotary cylinder or the circulating belt has an inner side and an outer side and wherein a particular number m of fastening devices are attached to the outer side of the rotary cylinder or of the circulating belt. Here, in each case one fastening device fastens in each case one individual element at in each case one predetermined position on the surface of the moving substrate web.

The invention relates to a method and a device for applying and fastening individual elements at predetermined positions on a surface of a moving substrate web.

For this purpose, a “fluidic self-assembly process”, in which integrated circuits, so-called chips, are “flushed” or washed into recesses of a film, is known, for example, from WO 03/0548808 A2, U.S. Pat. No. 6,417,025 or WO 01/33621 A2. By way of example, a carrier film in endless form is provided with recesses which comprise approximately the size of the chip to be deposited. The recesses are in this case distributed over the endless film in such a way that when the film is subsequently divided into individual security elements, the desired number of chips is contained in the security element. In the next step, a liquid containing the chips is poured over the film prepared in this way. In this case, the chips are washed into the recesses and orient themselves in this manner.

Furthermore, the “pick-and-place” method is known from the prior art, in which method a gripper arm takes an individual element from a storage container and positions it at a desired point of a substrate web and fastens it there. However, this method has the disadvantage that it is very slow and therefore cannot apply a multiplicity of individual elements to the substrate web in a short amount of time.

The invention is therefore based on the object of further developing a method of the generic type in such a way that the disadvantages of the prior art are remedied.

Said object is achieved by way of the features of the independent claims. Developments of the invention are the subject of the dependent claims.

According to the invention, the method comprises the following steps of:
a) providing a rotative cylinder or a circulating belt, wherein the rotative cylinder or the circulating belt comprises an inner side and an outer side,
b) providing a determined number m of fastening devices on the outer side of the rotative cylinder or of the circulating belt, such that a respective individual element can be fastened at a respective predetermined position on the outer side of the rotative cylinder or of the circulating belt by a respective fastening device and no individual element can be fastened outside of the fastening devices,
c) supplying a number n of individual elements to the outer side of the rotative cylinder or of the circulating belt, wherein the number n is greater than or equal to the number m or wherein a plurality of individual elements are available at each individual fastening device, wherein the individual elements that come into contact with a fastening device are fastened to the outer side of the rotative cylinder or of the circulating belt by the fastening device,
d) removing the individual elements that are not fastened to the outer side of the rotative cylinder or of the circulating belt by a fastening device from the outer side of the rotative cylinder or of the circulating belt,
e) bringing the outer side of the rotative cylinder or of the circulating belt into contact with the surface of the moving substrate web and transferring the individual elements from the outer side of the rotative cylinder or of the circulating belt to the surface of the moving substrate web,
f) repeating steps c) to e) until a respective individual element has been fastened at all of the predetermined positions on the surface of the moving substrate web.

The device according to the invention comprises a rotative cylinder or a circulating belt, wherein the rotative cylinder or the circulating belt comprises an inner side and an outer side and wherein a determined number m of fastening devices are attached to the outer side of the rotative cylinder or of the circulating belt. Here, a respective fastening device fastens a respective individual element at a respective predetermined position on the surface of the moving substrate web.

The term “individual element” in this case denotes electrical or electronic components or parts such as for example microprocessors with and without integrated antennas, LEDs, sensors, batteries, solar cells, resistors, capacitors, transistors or the like. Said term additionally also comprises optical elements such as for example lenses, Fresnel lenses or polarizers, and also security elements for security documents.

Possible as “substrate web” are roll goods in the form of paper, plastic, glass or textile and any type of composite materials, for example carbon-fiber-reinforced materials. The same materials may also be present and processed in the form of sheets, in the form of plates or in the form of cut-to-size panels. The web width may for example be 1 m or more, and the web speed of a moving substrate web is typically at least 1 m/min. Here, the surface of the moving substrate web is the front and/or rear side of the substrate web and in particular not the side surfaces thereof, the area of which in relation to the area of the front or rear side is negligibly low.

Predetermined positions on a surface of a moving substrate web are predetermined and defined by a user, that is to say are not arranged stochastically or randomly. Preferably, the predetermine positions are arranged in a grid-like or regular manner in columns and rows on the surface of the substrate web, wherein the columns and rows each comprise a predetermined spacing from one another. It goes without saying that an arrangement with a predefined offset between the rows and/or columns is also possible, or the rows and/or columns can be arranged in the form of curved or jagged lines.

The predetermined position on the outer side of the rotative cylinder or of the circulating belt, at which a respective individual element can be fastened and at which the fastening devices are located, correspond with the predetermined positions on the surface of the moving substrate web. This means that the fastening devices are arranged on the outer side of the rotative cylinder or of the circulating belt such that they apply the individual elements at the predetermined positions on the surface of the moving substrate web. The arrangement of the fastening devices on the outer side of the rotative cylinder thus corresponds to the arrangement of the predetermined positions on the surface of the moving substrate web.

All adhesives known from the prior art which fasten an individual element to the substrate web in such a way that the individual element immediately adheres to the substrate web without being removed from the substrate web again during the movement of the substrate web can be used as adhesive.

Applications of the elements positioned according to the invention concern, for example, security documents such as bank notes or ID cards with chips or else packaging material, labels or other two-dimensional products. In this case, it is for example possible to apply optical elements in order to increase the visual attractiveness. In another example, chips for processing, storing and outputting data, for example for authentication purposes, are used. Furthermore, other functionalities such as sensors are also conceivable.

According to a further advantageous refinement of the method, provision is made for the substrate web, after said substrate web has been provided with the individual elements, to be cut up into individual uses. Such uses are for example the aforementioned security documents.

According to a preferred embodiment, provision is made for the number n of individual elements to be equal to the number m of fastening devices. Here, the method step c) is carried out until a respective individual element is located on all of the fastening devices. Thus, after conclusion of method step d), exactly one individual element is located on each fastening device.

According to a further advantageous refinement of the method, it is provided that, in step c), the number n of individual elements are supplied to the outer side of the rotative cylinder or of the circulating belt by pouring and/or washing and/or spraying and/or blowing the individual elements onto the outer side of the rotative cylinder or of the circulating belt.

According to a further advantageous embodiment, it is provided that, in step d), the individual elements that are not fastened to the outer side of the rotative cylinder or of the circulating belt by a fastening device are removed from the outer side of the rotative cylinder or of the circulating belt by said individual elements being wiped and/or blown and/or suctioned and/or caused to fall off of the outer side of the rotative cylinder or of the circulating belt. Surplus individual elements, which can no longer be assigned to any free fastening device, are thus removed from the rotative cylinder or the circulating belt again.

According to a further advantageous refinement of the method, provision is made for a recess to be introduced into the surface of the moving substrate web at at least one, preferably at all of the predetermined positions on the surface of the moving substrate web, wherein the area of the respective recess is of such a size that a respective individual element can be introduced into a respective recess. This has the particular advantage that during removal of surplus individual elements, for example by wiping them off, the already fixedly adhesively bonded individual elements are not torn off of the substrate web again. In this case, an adhesive can be located in the recesses, which additionally fastens the individual elements in the recess.

According to a further advantageous embodiment, provision is made for the fastening devices to be formed by openings in the outer side of the rotative cylinder or of the circulating belt, through which openings the individual elements are suctioned onto the outer side of the rotative cylinder or of the circulating belt by means of negative pressure, wherein the negative pressure is generated in the interior of the rotative cylinder or on the inner side of the circulating belt. In this case, the area of the respective opening is so small that no individual element passes through, and thus does not slip through the opening. The individual elements are thus suctioned in the openings on the outer side of the rotative cylinder or of the circulating belt by way of a negative pressure.

As an alternative thereto, the fastening devices can also be formed by magnets or electrostatic devices or adhesive devices, which are attached to the outer side of the rotative cylinder or of the circulating belt.

In this case, it is particularly preferably provided that, in step e), the transfer of the individual elements from the outer side of the rotative cylinder or of the circulating belt to the surface of the moving substrate web is made possible or made easier by deactivating the negative pressure or the magnetic field of the magnet or the electrostatic device or the adhesive device.

In addition, the individual elements can also be pressed from the outer side of the rotative cylinder or of the circulating belt onto the surface of the moving substrate web by way of a positive pressure in the interior of the rotative cylinder or on the inner side of the circulating belt or a polarity reversal of the magnetic field of the magnet.

In addition, it is also possible for the moving substrate web to be porous at the intended positions, such that a vacuum or negative pressure can be applied through the substrate web, said vacuum or negative pressure, at the porous points, providing assistance in the transfer of the individual elements provided by the cylindrical or belt-shaped supply system. As a result, the individual elements are positioned, and optionally fixed, at the intended positions on the substrate web.

If an adhesive devices is used, the surface of the substrate web may particularly advantageously comprise a stronger adhesive coating, such that the individual elements adhere more firmly to the substrate web than to the rotative cylinder or the circulating belt, which facilitates the transfer from the rotative cylinder or circulating belt to the substrate web.

According to a further advantageous embodiment, the individual elements, after they have been applied to the moving substrate web, are additionally fixedly adhesively bonded and/or encapsulated, wherein the encapsulation may for example consist of an areal or partial lamination or a lacquer encapsulation. In this way, said individual elements are intended to be fastened to the moving substrate web in a particularly firm manner.

According to a further advantageous embodiment, the rotative cylinder can comprise milled recesses or shaped recesses which are produced in some other way, which, in step c), lead to an orientation or alignment of the individual elements relative to the surface of the rotative cylinder or of the circulating belt.

It goes without saying that the features mentioned above can be used not only in the specified combinations but also in other combinations without departing from the scope of the present invention, provided this is covered by the scope of protection of the claims.

1.-14. (canceled)

15. A method for applying and fastening individual elements at predetermined positions on a surface of a moving substrate web, characterized by the following steps of:
a) providing a rotative cylinder or a circulating belt, wherein the rotative cylinder or the circulating belt comprises an inner side and an outer side,
b) providing a determined number m of fastening devices on the outer side of the rotative cylinder or of the circulating belt, such that a respective individual element can be fastened at a respective predetermined position on the outer side of the rotative cylinder or of the circulating belt by a respective fastening device and no individual element can be fastened outside of the fastening devices,
c) supplying a number n of individual elements to the outer side of the rotative cylinder or of the circulating belt, wherein the number n is greater than or equal to the number m, wherein the individual elements that come into contact with a fastening device are fastened to the outer side of the rotative cylinder or of the circulating belt by the fastening device,
d) removing the individual elements that are not fastened to the outer side of the rotative cylinder or of the circulating belt by a fastening device from the outer side of the rotative cylinder or of the circulating belt,
e) bringing the outer side of the rotative cylinder or of the circulating belt into contact with the surface of the moving substrate web and transferring the individual elements from the outer side of the rotative cylinder or of the circulating belt to the surface of the moving substrate web,
f) repeating steps c) to e) until a respective individual element has been fastened at all of the predetermined positions on the surface of the moving substrate web.

16. The method according to claim 15, wherein the number n of individual elements is equal to the number m of fastening devices and step c) is carried out until a respective individual element is located on all of the fastening devices.

17. The method according to claim 15, wherein, in step c), the number n of individual elements are supplied to the outer side of the rotative cylinder or of the circulating belt by pouring and/or washing and/or spraying and/or blowing the individual elements onto the outer side of the rotative cylinder or of the circulating belt.

18. The method according to claim 15, wherein, in step d), the individual elements that are not fastened to the outer side of the rotative cylinder or of the circulating belt by a fastening device are removed from the outer side of the rotative cylinder or of the circulating belt by said individual elements being wiped and/or blown and/or suctioned and/or caused to fall off of the outer side of the rotative cylinder or of the circulating belt.

19. The method according to claim 15, wherein a recess is introduced into the surface of the moving substrate web at at least one, at all of the predetermined positions on the surface of the moving substrate web,
wherein the area of the respective recess is of such a size that a respective individual element can be introduced into a respective recess.

20. The method according to claim 15, wherein the individual elements are electronic or electrical parts or components or security elements or optical elements.

21. The method according to claim 15, wherein the fastening devices are formed by openings in the outer side of the rotative cylinder or of the circulating belt, through which openings the individual elements are suctioned onto the outer side of the rotative cylinder or of the circulating belt by means of negative pressure,
wherein the area of the respective opening is so small that no individual element passes through and
wherein the negative pressure is generated in the interior of the rotative cylinder or on the inner side of the circulating belt.

22. The method as according to claim 15, wherein the fastening devices are formed by magnets or electrostatic devices or adhesive devices, which are attached to the outer side of the rotative cylinder or of the circulating belt.

23. The method according to claim 21, wherein, in step e), the transfer of the individual elements from the outer side of the rotative cylinder or of the circulating belt to the surface of the moving substrate web is made possible by deactivating the negative pressure or the magnetic field of the magnet or the electrostatic device or the adhesive device.

24. The method according to claim 22, wherein the individual elements are pressed from the outer side of the rotative cylinder or of the circulating belt onto the surface of the moving substrate web by way of a positive pressure in the interior of the rotative cylinder or on the inner side of the circulating belt or a polarity reversal of the magnetic field of the magnet.

25. The method according to claim 15, wherein the individual elements are fixedly adhesively bonded and/or encapsulated on the moving substrate web.

26. A device for applying and fastening individual elements at predetermined positions on a surface of a moving substrate web,
wherein the device comprises a rotative cylinder or a circulating belt,
wherein the rotative cylinder or the circulating belt comprises an inner side and an outer side,
wherein a determined number m of fastening devices are attached to the outer side of the rotative cylinder or of the circulating belt and
wherein a respective fastening device fastens a respective individual element at a respective predetermined position on the surface of the moving substrate web.

27. The device according to claim 26, wherein the fastening devices are openings in the outer side of the rotative cylinder or of the circulating belt, through which openings the individual elements can be suctioned onto the outer side of the rotative cylinder or of the circulating belt by means of negative pressure,
wherein the area of the respective opening is so small that no individual element passes through and
wherein the negative pressure is applied in the interior of the rotative cylinder or on the inner side of the circulating belt.

28. The device according to claim 26, wherein the fastening devices are magnets or electrostatic devices or adhesive devices, which are attached to the outer side of the rotative cylinder or of the circulating belt.
